(19) United States
(12) Patent Application Publication
(10) Pub. No.: US 2024/0176586 A1
(43) Pub. Date: May 30, 2024

(54) IN-MEMORY COMPUTATION SYSTEM WITH COMPACT STORAGE OF SIGNED COMPUTATIONAL WEIGHT DATA

(71) Applicant: STMicroelectronics S.r.l., Agrate Brianza (MB) (IT)

(72) Inventors: Marcella CARISSIMI, Treviolo (IT); Paolo Sergio ZAMBOTTI, Milano (IT); Riccardo ZURLA, Binasco (MI) (IT)

(73) Assignee: STMicroelectronics S.r.l., Agrate Brianza (MB) (IT)

(21) Appl. No.: 17/994,817

(22) Filed: Nov. 28, 2022

(51) Int. Cl. G06F 7/544; G11C 13/00

(52) U.S. Cl. CPC G06F 7/5443; G11C 13/0004; G11C 13/0026; G11C 13/0028

(57) ABSTRACT

An IMC circuit includes a memory cells arranged in matrix. Computational weights for an IMC operation are stored in groups of cells. Each row of groups of cells includes a positive and negative word linen. Each column of groups of cells includes a bit line. The IMC operation includes a first elaboration where a word line signal is applied to the positive/negative word line of the group of cells depending on the positive/negative sign, respectively, of the coefficient data, with a positive MAC output on the bit line. In a second elaboration, a word line signal is applied to the negative/positive word line of the group of cells depending on the positive/negative sign, respectively, of the coefficient data, with a negative MAC output on the bit line. The IMC operation result is obtained from a difference between the positive and negative MAC operations.

### TECHNICAL FIELD

Embodiments relate to an in-memory computation circuit and, in particular, to supporting a compact storage of signed computational weight data and the handling of feature or coefficient data in multiple bit formats.

### BACKGROUND

An in-memory computation (IMC) system stores information in the bit cells of a memory array and performs calculations at the bit cell level. An example of a calculation performed by an IMC system is a multiply and accumulate (MAC) operation where an input array of numbers (X values, also referred to as the feature or coefficient data) are multiplied by an array of computational weights (g values) stored in the memory and the products are added together to produce an output array of numbers (Y values).

$$[ \begin{matrix}{Y}_{1} \\ {Y}_{2} \\ ⋮ \\ {Y}_{m}\end{matrix} ] = [ \begin{matrix}{ℊ}_{11} & {ℊ}_{12} & ⋯ & {ℊ}_{1 n} \\ {ℊ}_{21} & {ℊ}_{22} & ⋯ & {ℊ}_{2 n} \\ ⋮ & ⋮ & ⋮ & ⋮ \\ {ℊ}_{m 1} & {ℊ}_{m 2} & ⋯ & {ℊ}_{mn}\end{matrix} ] \times [ \begin{matrix}{X}_{1} \\ {X}_{2} \\ ⋮ \\ {X}_{n}\end{matrix} ]$$

$$\{ \begin{matrix}{Y}_{1} = {ℊ}_{11} \times {X}_{1} + {ℊ}_{12} \times {X}_{2} + ⋯ + {ℊ}_{1 n} \times {X}_{n} \\ {Y}_{2} = {ℊ}_{21} \times {X}_{1} + {ℊ}_{22} \times {X}_{2} + ⋯ + {ℊ}_{2 n} \times {X}_{n} \\ ⋮ \\ {Y}_{m} = {ℊ}_{m 1} \times {X}_{1} + {ℊ}_{m 2} \times {X}_{2} + ⋯ + {ℊ}_{mn} \times {X}_{n}\end{matrix}$$

By performing these calculations at the bit cell level in the memory, the IMC system does not need to move data back and forth between a memory device and a computing device. Thus, the limitations associated with data transfer bandwidth between devices are obviated and the computation can be performed with lower power consumption.

Reference is made to FIG. 1 which shows a schematic diagram of an analog in-memory computation circuit 10. The circuit 10 utilizes a memory array 12 formed by a plurality of memory cells 14 arranged in a matrix format having m columns and n rows. Each memory cell 14 is programmed to store a bit of data g_{ab}, where a is an integer from 1 to m and b is an integer from 1 to n, relating to the computational weights (also referred to as kernel data) for an in-memory compute operation. Each bit of the computational weight has either a logic “1” value or a logic “0” value which is represented, for example, by a programmable transconductance in the memory cell 14.

In an embodiment of the memory array 12, each memory cell 14 comprises a phase change memory (PCM) cell formed by a select circuit (MOSFET transistor, BJT transistor, diode device, etc.) 14t operating as a switching element and a variable resistive element 14r providing a programmable transconductance. In the case of a MOSFET transistor for the select circuit 14t, the control node (gate) of the MOSFET transistor is connected to the word line WL. The source-drain path of the MOSFET transistor is connected in series with the variable resistive element 14r between the bit line BL and a reference node (for example, a source line or ground). More specifically, a drain of the MOSFET transistor is connected to a first terminal of the variable resistive element 14r, the source of the MOSFET transistor is connected to the reference node, and the second terminal of the variable resistive element 14r is connected to the bit line BL.

As is well known to those skilled in the art, a PCM-type memory cell 14 is configured to store data using a phase change material (such as a chalcogenide) that is capable of stably transitioning between amorphous and crystalline phases according to an amount of heat transferred thereto. The amorphous and crystalline phases exhibit two or more distinct resistances (corresponding to the variable resistive element 14r), in other words two or more distinct transconductances, which are used to distinguish two or more distinct logic states programmable into the memory cell. The amorphous phase exhibits a relatively higher resistance (i.e., a lower transconductance) and thus the current sunk from the bit line BL by the memory cell programmed in this state when selected by assertion of the word line signal at the gate of the select circuit 14t is relatively smaller. Conversely, the crystalline phase exhibits a relatively lower resistance (i.e., a higher transconductance) and thus the current sunk from the bit line BL by the memory cell programmed in this state when selected by assertion of the word line signal at the gate of the select circuit 14t is relatively larger.

In an embodiment for a specific, but non-limiting, example for two distinct logic states: the amorphous phase may represent programming of the memory cell to logic “0” (or reset state) for the associated coefficient weight and the crystalline phase may represent programming of the memory cell to logic “1” (or set state) for the associated coefficient weight.

It will be understood that other memory cell types could instead be used for the array 12. For example, magnetoresistive random access memory (MRAM) cells or resistive random access memory (RRAM) cells could be used. The memory cell may alternatively comprise a static random access memory (SRAM) cell.

Each memory cell 14 includes a word line WL and a bit line BL. The memory cells 14 in a common row of the matrix are connected to each other through a common word line WL<b>. The memory cells 14 in a common column of the matrix are connected to each other through a common bit line BL<a>.

Each word line WL<b> is driven by a word line driver circuit 16 with a pulsed word line signal generated by a row controller circuit 18. The word line driver circuit 16 may be implemented as a CMOS driver circuit (for example, a series connected p-channel and n-channel MOSFET transistor pair forming a logic inverter circuit).

The row controller circuit 18 receives an address signal (Address) for the in-memory compute operation and in response thereto performs the function of selecting which ones of the word lines WL<1> to WL<n> are to be simultaneously accessed (or actuated) in parallel during an analog in-memory compute operation. The row controller circuit 18 further receives the feature or coefficient data X_{b} for the in-memory compute operation and in response thereto controls, for each corresponding actuated word line WL<b>, the width (i.e., the on time T_{ON}) of the generated pulsed word line signal. This functionality is a form of a pulse width modulation (PWM) control for the applied word line signals dependent on the digital value of the received feature or coefficient data X.

FIG. 1 illustrates, by way of example only, the simultaneous actuation of all word lines WL<1>, . . . , WL<n> in response to the received Address with pulsed word line signals having pulse widths set by the digital value of the corresponding coefficient data X₁, . . . , Xₙ. It will, of course, be understood that the analog in-memory compute operation may instead utilize a simultaneous actuation of fewer than all rows of the memory array (through either Address signal selection or through a zero value for a given coefficient data X_{b}).

The analog signal Yₐ developed on the bit line BL<a> is dependent on the logic state of the bits of the computational weight g_{ab} stored in the b=1 to n memory cells 14 of the column and the widths of the pulsed word line signals applied to the word lines WL<1>, . . . , WL<n> for those memory cells 14. More specifically, it will be understood that each memory cell 14 contributes a bit line BL discharge current that is proportional to X_{b}×g_{ab}. So, in the example shown in FIG. 1 where the word line signals 16 are simultaneously applied to the word lines WL<1>, . . . , WL<n>, the analog signal Y₁ developed on the bit line BL<1> is proportional to the sum of discharge currents due to X₁×g₁₁, X₂×g₁₂, . . . , and Xₙ×g₁ₙ.

A column processing circuit 20 senses and samples the analog signal Yₐ on each bit line BL<a> for the m columns and converts the analog signal to a corresponding digital signal dYₐ using analog-to-digital converter circuitry. Although FIG. 1 illustrates that one analog-to-digital converter (ADC) is provided for each column, it will be understood that ADC resources in the column processing circuit 20 could instead be shared by multiple columns using time division multiplexing. The column processing circuit 20 may further include digital signal processing circuitry for performing digital computations and calculations on the digital signals dYa to generate a decision output for the in-memory compute operation.

Although not explicitly shown in FIG. 1, it will be understood that the circuit 10 further includes conventional row decode, column decode, and read-write circuits known to those skilled in the art for use in connection with writing bits of data (for example, the computational weight data) to, and reading bits of data from, the memory cells 14 of the memory array 12. This operation is referred to as a conventional memory access mode and is distinguished from the analog in-memory compute operation discussed above.

Reference is now made to FIG. 2 which shows a circuit diagram for the row controller 18. A latch circuit 52_{b} is provided for each word line WL<b> to latch the corresponding digital value of the digital value of the coefficient data X_{b}. For example, this latching operation may be dependent on the address signal (Address), which is decoded to control the latch circuit 52_{b} to latch the coefficient data X_{b} for the corresponding word line WL<b>. A control circuit 50_{b} is provided for each word line WL<b>. The control circuit 50b receives a global start signal (Start) and the associated coefficient data X_{b} from latch circuit 52_{b}. If the latch value is zero, the global start signal is blocked and no word line signal is asserted for the analog in-memory compute operation. Otherwise, the latch circuit 52_{b} will assert its output signal Start to control the corresponding word line WL<b> to be asserted during the analog in-memory compute operation. A global counter circuit 54 increments a count value (Count) starting from a zero reset at the beginning of the in-memory compute operation. A compare circuit 56_{b} for each word line WL<b> is coupled to the latch circuit 52_{b} and compares the count value Count to the latched digital value of the coefficient data X_{b}. The output of the compare circuit 56_{b} is asserted when the count value Count meets or exceeds the latched digital value. A combinational logic circuit 58_{b} logically combines the outputs of the decoder circuit 50_{b} and the match circuit 56_{b} to generate the pulsed word line signal for application to the driver circuit 16 of the word line WL<b>. In an embodiment, the combinational logic circuit 58_{b} is a logic NAND gate.

Operation of the circuitry within the row controller 18 is as follows: At the beginning of the in-memory compute operation, the digital values of the coefficient data X₁ to Xₙ are latched by the latch circuits 52₁ to 52n, and the global counter 54 is reset. If the latched data value is non-zero, the Start_{b} signal output of the decoder circuit 50_{b} is asserted logic high (in response to the global start signal) and the output of the NAND gate 58_{b} transitions to logic high to provide the leading edge of the word line signal pulse. The global counter 54 then begins incrementing the Count value. When the incrementing Count value meets or exceeds the digital value of the coefficient data X_{b} latched by the latch circuit 52b, the finish signal output of the compare circuit 56_{b} is asserted logic high and the output of the NAND gate 58_{b} transitions to logic low to provide the trailing edge of the word line signal pulse. The pulse width (i.e., the on time T_{ON}) of the generated pulsed word line signal is thus dependent on the amount of time needed during the in-memory compute operation for the incrementing Count value to reach the digital value of the coefficient data X_{b}.

Reference is now made to FIG. 3 which shows a simplified timing diagram for operation of the circuit 10 in connection with one overall in-memory compute operation including one elaboration. At time t1, a latch control signal is asserted to cause the latch circuits 52₁ to 52n to latch the digital values of the coefficient data X₁ to Xₙ, and the overall in-memory compute operation begins. We assume here the example discussed above and shown in FIG. 1 where there is a simultaneous selection of all rows of memory cells 14 in response to the loaded non-zero coefficient data, and the simultaneous actuation at time t2 of the word lines WL<1> to WL<n> corresponding to feature or coefficient data X₁ to Xₙ with pulsed word line signals in response to the Start_{b} signals. Also at time t2, the previously reset Count value begins to increment. At time t3, the incrementing Count value meets or exceeds the digital value of the coefficient data X₁, and the word line signal pulse on the word line WL<1> terminates. At time t4, the incrementing Count value meets or exceeds the digital value of the coefficient data X₃, and the word line signal pulse on the word line WL<3> terminates. At time t5, the incrementing Count value meets or exceeds the digital value of the coefficient data X₂ and X_{N}, and the word line signal pulses on the word lines WL<2> and WL<N> terminates. At time t6, the Start_{b} signals are deasserted and the Count value is reset. At time t7, the analog signals Y₁ to Yₘ on the bit lines BL<1> to BL<m> are sampled for analog-to-digital conversion and the overall in-memory compute operation ends.

It is recognized that the value for feature or coefficient data can be signed and that the value for the computational weight data can also be signed. There exists a need in the art to support performance of signed MAC operations.

### SUMMARY

In an embodiment, an in-memory computation circuit comprises: a memory array including a plurality of memory cells arranged in a matrix with plural rows and plural columns, wherein groups of memory cells store computational weights for an in-memory compute (IMC) operation that is performed with a first multiply and accumulate (MAC) elaboration and a second MAC elaboration, each row of groups of memory cells including a positive word line coupled to a first memory cell in each group of memory cells and a negative word line coupled to a second memory cell in each group of memory cells, and each column of groups of memory cells including a bit line coupled to the first and second memory cells of each group of memory cells; a row controller circuit configured to receive signed coefficient data for the IMC operation and: a) generate during the first MAC elaboration a pulsed word line signal for application to the positive word line when the signed coefficient data is positive, and generate a pulsed word line signal for application to the negative word line when the signed coefficient data is negative; and b) generate during the second MAC elaboration a pulsed word line signal for application to the negative word line when the signed coefficient data is positive, and generate a pulsed word line signal for application to the positive word line when the signed coefficient data is negative; and a column processing circuit coupled to the bit line and configured to: a) sense a first analog signal developed on the bit line during the first MAC elaboration; and b) sense a second signal developed on the bit line during the second MAC elaboration.

In an embodiment, an in-memory computation circuit comprises: a memory array including a plurality of memory cells arranged in a matrix with plural rows and plural columns, wherein groups of memory cells store computational weights for an in-memory compute (IMC) operation that is performed with a first multiply and accumulate (MAC) elaboration and a second MAC elaboration, each row of groups of memory cells including a positive word line coupled to first and second memory cells in each group of memory cells and a negative word line coupled to third and fourth memory cells in each group of memory cells, and each column of groups of memory cells including a positive bit line coupled to the first and third memory cells of each group of memory cells and a negative bit line coupled to second and fourth memory cells of each group of memory cells; a row controller circuit configured to receive signed coefficient data for the IMC operation and generate during each of the first and second MAC elaborations a pulsed word line signal for application to the positive word line when the signed coefficient data is positive, and generate a pulsed word line signal for application to the negative word line when the signed coefficient data is negative; and a column processing circuit coupled to the positive and negative bit lines and configured to: a) sense a first analog signal developed on the positive bit line during the first MAC elaboration; and b) sense a second signal developed on the negative bit line during the second MAC elaboration.

### BRIEF DESCRIPTION OF THE DRAWINGS

For a better understanding of the embodiments, reference will now be made by way of example only to the accompanying figures in which:

FIG. 1 is a schematic diagram of an embodiment for an in-memory computation circuit;

FIG. 2 shows a circuit diagram for a row controller circuit used by the in-memory computation circuit of FIG. 1;

FIG. 3 is a timing diagram illustrating an in-memory compute operation using the circuit of FIG. 1;

FIG. 4 is a schematic diagram of an embodiment for an in-memory computation circuit;

FIG. 5 shows a circuit diagram for a row controller circuit used by the in-memory computation circuit of FIG. 4;

FIG. 6 is a timing diagram illustrating an in-memory compute operation using the circuit of FIG. 4;

FIG. 7 is a schematic diagram of an embodiment for an in-memory computation circuit;

FIG. 8 shows a circuit diagram for a row controller circuit used by the in-memory computation circuit of FIG. 7;

FIG. 9 is a timing diagram illustrating an in-memory compute operation using the circuit of FIG. 7;

FIG. 10 shows a circuit diagram for an embodiment of a row controller circuit used by the in-memory computation circuit of FIG. 7; and

FIG. 11 is a timing diagram illustrating an in-memory compute operation using the circuit of FIG. 7.

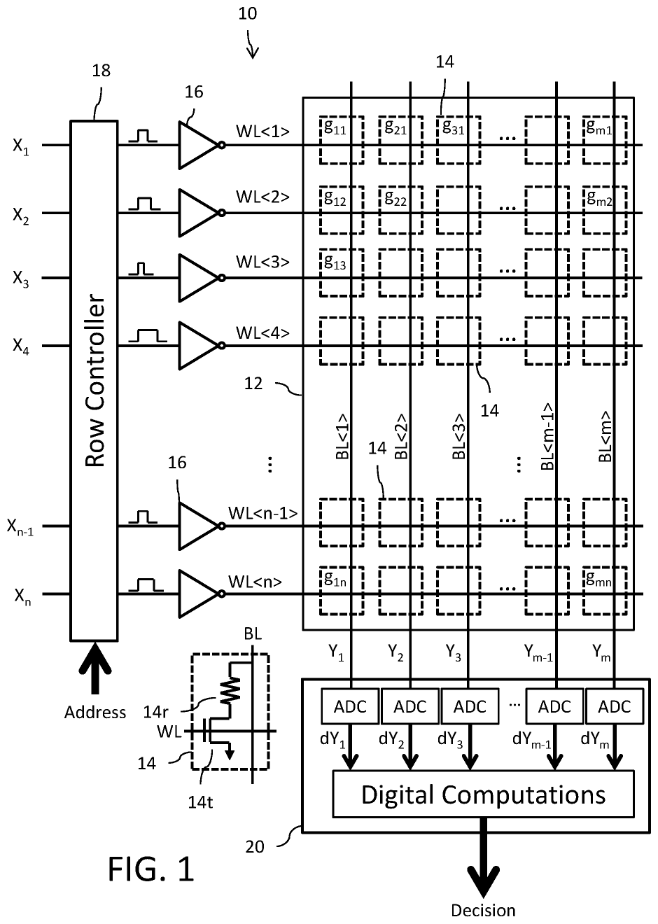

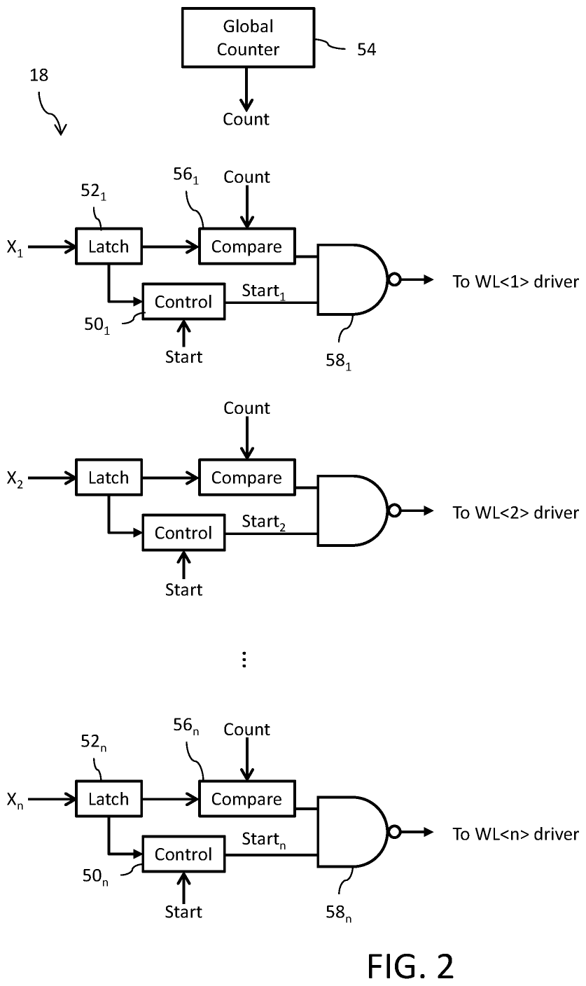

### DETAILED DESCRIPTION OF THE DRAWINGS

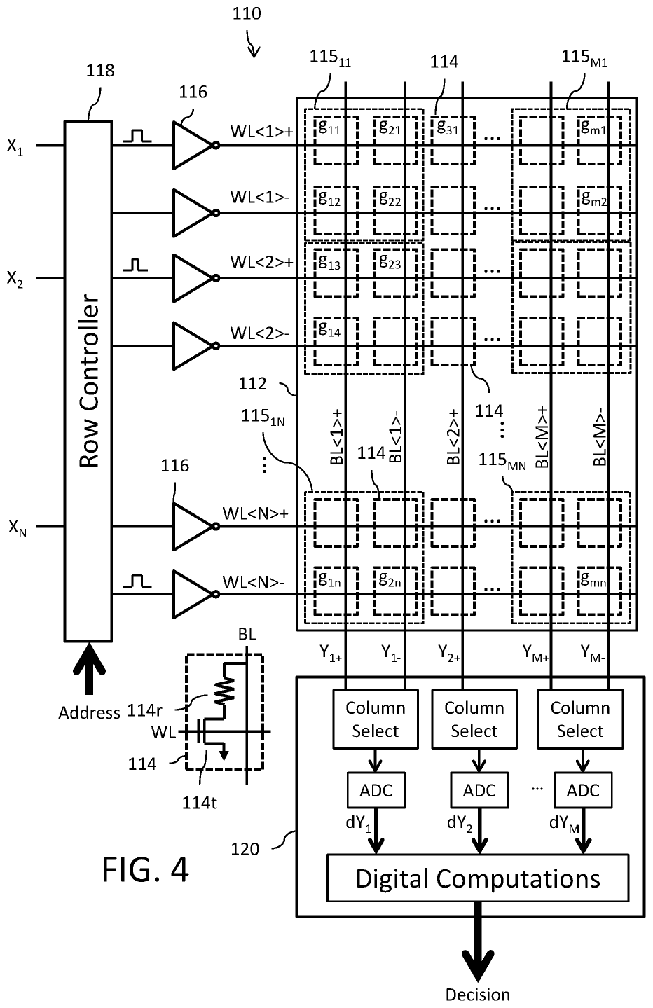

Reference is now made to FIG. 4 which shows a schematic diagram of an in-memory computation circuit 110. The circuit 110 utilizes a memory array 112 formed by a plurality of memory cells 114 arranged in a matrix format having m columns and n rows. The array 112 is arranged to include groups 115₁₁ to 115_{MN} of memory cells 114, wherein each group 115_{AB} includes four memory cells arranged in a 2×2 matrix across two rows and two columns of the array 112, where A is an integer from 1 to M and B is an integer from 1 to N. With this arrangement, there are N rows of groups 115_{AB} and M columns of groups 115_{AB} (where N=n/2 and M=m/2). Although the memory cells 114 of a group 115_{AB} are shown to be located in adjacent ones of the m columns of the array 112, it will be understood that this is by way of example only to ease the illustration and that in a preferred implementation the cells will most likely be separated from each other using a column multiplexing format as is well known to those skilled in the art.

Each group 115_{AB} of memory cells 114 stores a signed computational weight (also referred to as kernel data) for an in-memory compute operation. Each memory cell 114 can be programmed to store a bit of data gab, where a is an integer from 1 to m and b is an integer from 1 to n, for the signed computational weight of the group 115_{AB}. Each bit of data has either a logic “1” or a logic “0” value which is represented, for example, by a programmable transconductance in the memory cell 114. A signed computational weight of “+1” for a given group 115_{AB} is represented by programming logic “1” in the memory cells 114 of the main diagonal of the 2×2 matrix (for example, see g₁₁=1 and g₂₂=1 of group 115₁₁), and programming logic “0” in the memory cells 114 of the antidiagonal of the 2×2 matrix (for example, see g₁₂=0 and g₂₁=0 of group 115₁₁) as illustrated here:

$$[ \begin{matrix}1 & 0 \\ 0 & 1\end{matrix} ] ,$$

this being referred to in the art as the identity matrix. A signed computational weight of “−1” for a given group 115_{AB} is represented by programming logic “0” in the memory cells 114 of the main diagonal of the 2×2 matrix (for example, see g₁₁=0 and g₂₂=0) and programming logic “1” in the memory cells 114 of the antidiagonal of the 2×2 matrix (for example, see g₁₂=1 and g₂₁=1 of group 115₁₁) as illustrated here:

$$[ \begin{matrix}0 & 1 \\ 1 & 0\end{matrix} ] ,$$

this being referred to in the art as the exchange (or backward identity) matrix. A signed computational weight of “0” for a given group 115_{AB} is represented by programming logic “0” in all memory cells of the 2×2 matrix (for example, see g₁₁=0, g₂₂=0, g₁₂=0 and g₂₁=0 of group 115₁₁) as illustrated here:

$$[ \begin{matrix}0 & 0 \\ 0 & 0\end{matrix} ] ,$$

this being referred to in the art as the zero matrix.

In an embodiment of the memory array 112, each memory cell 114 comprises a phase change memory (PCM) cell formed by a select circuit (MOSFET transistor, BJT transistor, diode device, etc.) 114t operating as a switching element and a variable resistive element 114r providing a programmable transconductance. In the case of a MOSFET transistor for the select circuit 114t, the control node (gate) of the MOSFET transistor is connected to the word line WL. The source-drain path of the MOSFET transistor is connected in series with the variable resistive element 114r between the bit line BL and a reference node (for example, a source line or ground). More specifically, a drain of the MOSFET transistor is connected to a first terminal of the variable resistive element 114r, the source of the MOSFET transistor is connected to the reference node, and the second terminal of the variable resistive element 114r is connected to the bit line BL.

As is well known to those skilled in the art, a PCM-type memory cell 114 is configured to store data using a phase change material (such as a chalcogenide) that is capable of stably transitioning between amorphous and crystalline phases according to an amount of heat transferred thereto. The amorphous and crystalline phases exhibit two or more distinct resistances (corresponding to the variable resistive element 114r), in other words two or more distinct transconductances, which are used to distinguish two or more distinct logic states programmable into the memory cell. The amorphous phase exhibits a relatively higher resistance (i.e., a lower transconductance) and thus the current sunk from the bit line BL by the memory cell programmed in this state when selected by assertion of the word line signal at the gate of the select circuit 114t is relatively smaller. Conversely, the crystalline phase exhibits a relatively lower resistance (i.e., a higher transconductance) and thus the current sunk from the bit line BL by the memory cell programmed in this state when selected by assertion of the word line signal at the gate of the select circuit 114t is relatively larger.

In an embodiment for a specific, but non-limiting, example for two distinct logic states: the amorphous phase may represent programming of the memory cell to logic “0” (or reset state) for the associated coefficient weight and the crystalline phase may represent programming of the memory cell to logic “1” (or set state) for the associated coefficient weight.

It will be understood that other memory cell types could instead be used for the array 112. For example, magnetoresistive random access memory (MRAM) cells or resistive random access memory (RRAM) cells could be used. The memory cell may alternatively comprise a static random access memory (SRAM) cell.

Each memory cell 114 includes a word line WL and a bit line BL. The memory cells 114 in a common row of the matrix are connected to each other through a common word line WL. The groups 115_{AB} of memory cells 114 in a common row of groups 115_{AB} are connected to each other through a positive word line WL<B>+ and a negative word line WL<B>− (which form a word line pair for the common row of groups 115_{AB}). More specifically, the positive word line WL<B>+ is connected to the upper two memory cells in the 2×2 matrix for the group (for example, see WL<1>+ for g₁₁ and g₂₁ of group 115₁₁), while the negative word line WL<B>− is connected to the lower two memory cells in the 2×2 matrix for the group (for example, see WL<1>− for g₁₂ and g₂₂ of group 115₁₁).

The memory cells 114 in a common column of the matrix are connected to each other through a common bit line BL. The groups 115_{AB} of memory cells 114 in a common column of groups 115_{AB} are connected to each other through a positive bit line BL<A>+ and a negative bit line BL<A>− (which form a bit line pair for the common column of groups 115_{AB}). More specifically, the positive bit line BL<A>+ is connected to the left two memory cells in the 2×2 matrix for the group (for example, see BL<1>+ for g₁₁ and g₁₂ of group 115₁₁), while the negative bit line BL<A>− is connected to the right two memory cells in the 2×2 matrix for the group (for example, see BL<1>− for g₂₁ and g₂₂ of group 115₁₁).

Each word line WL is driven by a word line driver circuit 116 with a pulsed word line signal generated by a row controller circuit 118. The word line driver circuit 116 may be implemented as a CMOS driver circuit (for example, a series connected p-channel and n-channel MOSFET transistor pair forming a logic inverter circuit).

The row controller circuit 118 receives the signed feature or coefficient data X₁ to X_{N} for the in-memory compute operation. The row controller circuit 118 also receives an address signal (Address) for the in-memory compute operation and in response thereto selectively loads the signed feature or coefficient data X₁ to X_{N} for association with the rows of groups 115_{AB} of memory cells 114 which are to be simultaneously selected in parallel during each elaboration of the analog in-memory compute operation. During the simultaneous access for a given elaboration, only one word line of each word line pair (WL<B>+ or WL<B>−) is actuated with a pulsed word line signal. The actuated one word line of the word line pair in each elaboration is selected based on the logic state of the sign bit of the feature or coefficient data X_{B}. For example, if the sign bit is logic 0, indicative of a positive coefficient data value, then the positive word line WL<B>+ is asserted during the elaboration. Conversely, if the sign bit is logic 1, indicative of a negative coefficient data value, then the negative word line WL<B>− is asserted during the elaboration. The row controller circuit 118 still further controls, for each corresponding actuated word line, the width (i.e., the on time T_{ON}) of the generated pulsed word line signal. This functionality is a form of a pulse width modulation (PWM) control for the applied word line signals dependent on the digital value of the received signed feature or coefficient data X_{B}.

In an embodiment, the signed feature or coefficient data X_{B} is provided in multi-bit signed binary format, with a 4-bit example as set forth in the following table:

| Decimal | Binary | Decimal | Binary |
|---|---|---|---|
| 0 | 0000 | 0 | 1000 |
| +1 | 0001 | −1 | 1001 |
| +2 | 0010 | −2 | 1010 |
| +3 | 0011 | −3 | 1011 |
| +4 | 0100 | −4 | 1100 |
| +5 | 0101 | −5 | 1101 |
| +6 | 0110 | −6 | 1110 |
| +7 | 0111 | −7 | 1111 |

The use of a 4-bit format for the signed feature or coefficient data X_{B} is just an example, it being understood that the signed feature or coefficient data X_{B} can use any selected number of bits depending on the computation application.

It will be noted that the most significant bit of the signed binary feature or coefficient data X_{B} provides the sign bit (logic 0 is positive, logic 1 is negative) used to control selection of the positive (WL<B>+) or negative (WL<B>−) word line of the word line pair during both of the first and second elaborations, while the remaining less significant bits provide the value specifying the pulse width duration for the word line signal applied to that selected word line of the word line pair for each elaboration.

FIG. 4 illustrates, by way of example only, the simultaneous selection of all rows of groups 115_{AB} of memory cells 114 in response to the non-zero feature or coefficient data, and further illustrates, by way of example only, an elaboration of the in-memory compute operation including the simultaneous actuation of certain positive word lines (WL<1>+ and WL<2>+, for example) corresponding to positively signed feature or coefficient data (X₁ and X₂, for example) with pulsed word line signals having pulse widths set by the digital value of the corresponding coefficient data, along with the simultaneous actuation of certain negative word lines (WL<N>−, for example) corresponding to negatively signed feature or coefficient data (X_{N}, for example) with pulsed word line signals having pulse widths set by the digital value of the corresponding coefficient data. It will, of course, be understood that the elaboration for the analog in-memory compute operation may instead utilize a simultaneous selection of fewer than all rows of groups 115_{AB} of memory cells 114 (through either Address signal selection or through a zero value for the coefficient data X_{B}).

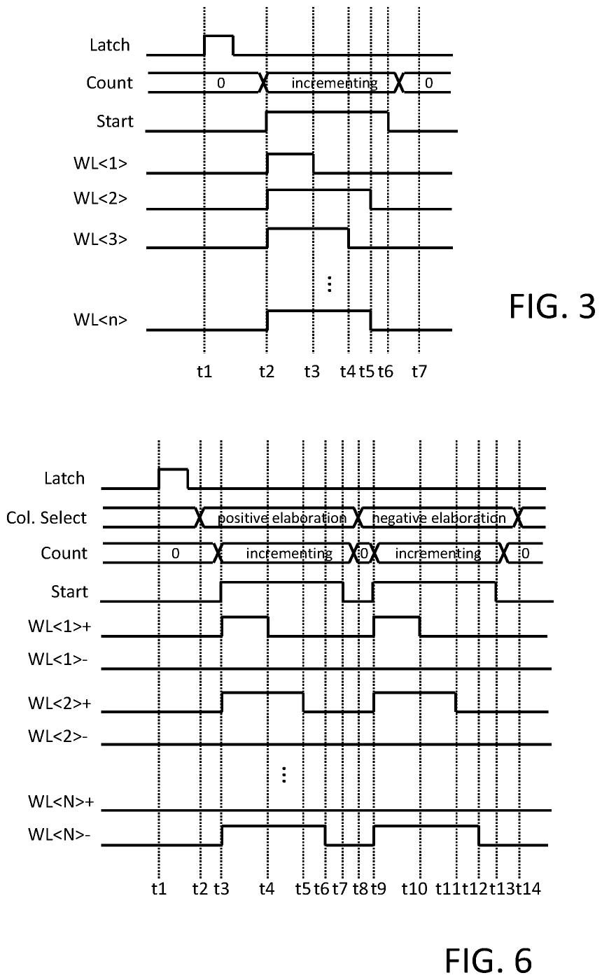

The analog signal Y_{A} developed during the elaboration on each bit line BL is dependent on the logic state of the bit of data g_{ab} for the signed computational weight stored in the memory cells 114 of the column and the widths of the pulsed word line signals applied to the word lines WL for those memory cells 114. More specifically, it will be understood that each memory cell 114 contributes a bit line BL discharge current during the elaboration that is proportional to X_{B}×g_{ab}. So, in the example shown in FIG. 3 where the word line signals are simultaneously applied to the word lines WL<1>+, WL<2>+, . . . , WL<N>−, the analog signal Y₁₊ developed during a first (e.g., positive) elaboration on the positive bit line BL<1>+ is proportional to the sum of discharge currents due to X_{1×}g₁₁, 0×g₁₂, X₂×g₁₃, 0×g₁₄, . . . , 0×g₁ₙ₋₁ and X_{N}×g₁ₙ. Likewise, the analog signal Y₁₋ developed during a second (e.g., negative) elaboration on the negative bit line BL<1>− is proportional to the sum of discharge currents due to X₁×g₂₁, 0×g₂₂, X₂×g₂₃, 0×g₂₄, ... , 0×g₂ₙ₋₁ and X_{N}×g₂ₙ. The overall result of the in-memory compute operation is a function of the difference between the first and second elaborations.

Let's assume now, for example only, some specific signed computational weights for the groups 115_{AB} of memory cells 114 in this column of groups. Group 115₁₁ is programmed with weight of −1 which is represented by the exchange matrix

$$[ \begin{matrix}0 & 1 \\ 1 & 0\end{matrix} ] .$$

Group 115₁₂ is programmed with weight of 0 which is represented by the zero matrix

$$[ \begin{matrix}0 & 0 \\ 0 & 0\end{matrix} ] .$$

Group 11_{1N} is programmed with weight of +1 which is represented by the identity

$$[ \begin{matrix}1 & 0 \\ 0 & 1\end{matrix} ] .$$

So, for this example, the analog signal Y₁₊ developed on the positive bit line BL<1>+ during the first (positive) elaboration of the in-memory compute operation is proportional to the sum of discharge currents due to X₁×0, 0×1, X₂×0, 0×0, . . . , 0×1 and X_{N}×0; which would result in zero discharge currents on the positive bit line BL<1>+. The analog signal Y₁-developed on the negative bit line BL<1>− during the second (negative) elaboration of the in-memory compute operation is proportional to the sum of discharge currents due to X₁×1, 0×0, X₂×0, 0×0, . . . , 0×0 and X_{N}×1; which result in a sum of discharge currents due to X₁×1, . . . , and X_{N}×1 on the negative bit line BL<1>−.

A column processing circuit 120 includes a column selection circuit coupled to the positive bit line BL<A>+ and negative bit line BL<A>− of each bit line pair. The column selection circuit functions as a multiplexer to selectively couple the positive bit line BL<A>+ to the ADC circuity during the first (positive) elaboration of the in-memory compute operation and then selectively couple the negative bit line BL<A>− to the ADC circuitry during the second (negative) elaboration of the in-memory compute operation. The ADC circuitry senses and samples the analog signal Y_{A+} developed during the first (positive) elaboration and then senses and samples the analog signal Y_{A-} developed during the second (negative) elaboration. Each of the analog signals is converted by the analog-to-digital converter circuitry to a corresponding digital signal dY_{A}. The column processing circuit 120 further includes digital signal processing circuitry for storing the resulting digital signals dY_{A} for the two elaborations and performing digital computations and calculations on the digital signals dY_{A} to generate a decision output for the in-memory compute operation. The further computations and calculations performed may include subtracting the digital signal dY_{A} generated from the second (negative elaboration) from the digital signal dY_{A} generated from the first (positive) elaboration to produce an output for the overall in-memory compute operation. Although FIG. 4 illustrates that one analog-to-digital converter (ADC) is provided for each bit line pair, it will be understood that ADC resources in the column processing circuit 120 could instead be shared by multiple bit line pairs using time division multiplexing.

Although not explicitly shown in FIG. 4, it will be understood that the circuit 110 further includes conventional row decode, column decode, and read-write circuits known to those skilled in the art for use in connection with writing bits of data (for example, the computational weight data) to, and reading bits of data from, the memory cells 114 of the memory array 112. This operation is referred to as a conventional memory access mode and is distinguished from the analog in-memory compute operation discussed above.

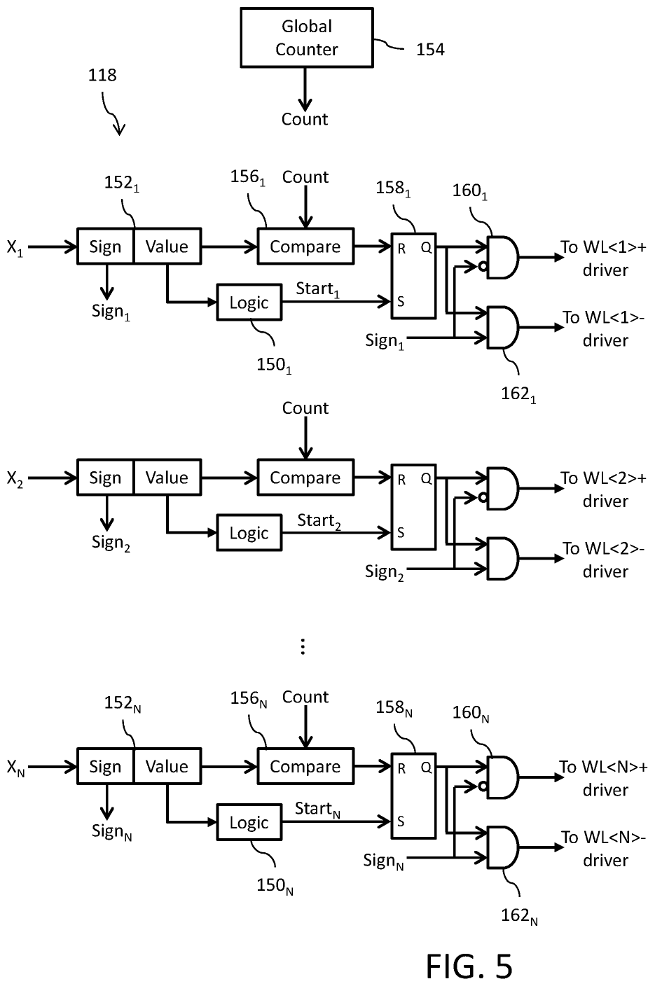

Reference is now made to FIG. 5 which shows a circuit diagram for the row controller 118. A latch circuit 152_{B} is provided for each row of groups 115_{AB} of memory cells 114 to latch, for example in response to a decoded Address value, the corresponding sign and value of the signed digital value of the coefficient data X_{B}. A logic circuit 150_{B} is provided for each row of groups 115_{AB} of memory cells 114. The logic circuits 150₁ to 150_{N} assert a start signal (Start_{B}), for example in response to a global start signal, at a beginning of each elaboration of the first (positive) and second (negative) elaborations of the in-memory compute operation. The generation of this start signal may, for example, be dependent on the corresponding signed digital value of the coefficient data X_{B} having a non-zero value for the analog in-memory compute operation. A global counter circuit 154 increments a count value (Count) starting from a zero reset at the beginning of each elaboration for the in-memory compute operation, wherein the elaboration ends when the Count reaches a maximum value. A compare circuit 156_{B} for each row of groups 115_{AB} of memory cells 114 is coupled to the latch circuit 152_{B} and compares the count value Count to the latched digital value of the coefficient data X_{B}. The output of the compare circuit 156_{B} is asserted when the count value Count meets or exceeds the latched digital value. A set-reset latch circuit 158_{B} has a set (S) input coupled to receive the Start_{B} signal output from the logic circuit 150_{B} and a reset (R) input coupled to receive the output of the compare circuit 156_{B}. A combinational logic circuit 160_{B} logically combines the output (Q) of the set-reset latch circuit 158_{B} and the logical inverse of the sign bit Signs from the latch circuit 152_{B} to generate the pulsed word line signal for application to the driver circuit 116 of the positive word line WL<B>+. A combinational logic circuit 162_{B} logically combines the output (Q) of the set-reset latch circuit 158_{B} and the sign bit Sign_{B} from the latch circuit 152_{B} to generate the pulsed word line signal for application to the driver circuit 116 of the negative word line WL<B>−. In an embodiment, the combinational logic circuits 160_{B} and 162_{B} are logic AND gates.

Operation of the circuitry within the row controller 118 is as follows: At the beginning of the in-memory compute operation, the address signal Address is decoded to control selective loading of the digital values of the coefficient data X₁ to X_{N} for latching by the latch circuits 152₁ to 152_{N}, and the global counter 154 is reset. If the digital value of the coefficient data is non-zero, the logic circuit 150_{B} indicates selection of the row of groups 115_{AB} of memory cells 114, the start signal Starts output of the logic circuit 150_{B} is asserted logic high at the beginning of each elaboration of the first (positive) and second (negative) elaborations, and the set-reset latch circuit 158_{B} is set with its output Q logic high. If the sign bit Sign_{B} is logic 0, indicating that the digital value of the coefficient data X_{B} is positive, both inputs of the AND gate 160_{B} are logic high and the output of the AND gate 160_{B} transitions to logic high to provide the leading edge of the word line signal pulse on the positive word line WL<B>+. Conversely, if the sign bit Sign_{B} is logic 1, indicating that the digital value of the coefficient data X_{B} is negative, both inputs of the AND gate 162_{B} are logic high and the output of the AND gate 162_{B} transitions to logic high to provide the leading edge of the word line signal pulse on the negative word line WL<B>−. The global counter 154 then begins incrementing the Count value. When the incrementing Count value meets or exceeds the digital value of the coefficient data X_{B} latched by the latch circuit 152_{B}, the output of the compare circuit 156_{B} is asserted logic high, and the set-reset latch circuit 158_{B} is reset with its output Q logic low. This logic low output is applied to both of the AND gates 160_{B} and 162_{B}, and whichever output of those AND gates is logic high (corresponding to assertion of the word line signal pulse) will transition to logic low to provide the trailing edge of the word line signal pulse. The pulse width (i.e., the on time T_{ON}) of the generated pulsed word line signal is thus dependent on the amount of time needed during the elaboration of the in-memory compute operation for the incrementing Count value to reach the digital value of the coefficient data X_{B}. When the Count reaches its maximum value, the given elaboration ends.

Reference is now made to FIG. 6 which shows a simplified timing diagram for operation of the circuit 110 in connection with one overall in-memory compute operation including two separate elaborations. At time t1, a latch control signal is asserted to cause the latch circuits 152₁ to 152_{N} to latch the signed digital values of the coefficient data X₁ to X_{N}, and the overall in-memory compute operation begins. At time t2, the column select circuitry of the column processing circuit 120 selects the positive bit lines BL<A>+ through the multiplexing in connection with performing the first (positive) elaboration of the in-memory compute operation. We assume here the example discussed above and shown in FIG. 4 where there is a simultaneous selection of all rows of groups 115_{AB} of memory cells 114 in response to the non-zero values of the coefficient data, and the simultaneous actuation in response to assertion of the Start_{B} signals at time t3 of the word lines WL<1>+, WL<2>+ corresponding to the positive feature or coefficient data X₁, X₂ with pulsed word line signals and also the word line WL<N>− corresponding to the negative feature or coefficient data X_{N} with a pulsed word line signal. Also at time t3, the previously reset Count value begins to increment. At time t4, the incrementing Count value meets or exceeds the digital value of the coefficient data X₁, and the word line signal pulse on the positive word line WL<1>+ terminates. At time t5, the incrementing Count value meets or exceeds the digital value of the coefficient data X₂, and the word line signal pulse on the positive word line WL<2>+ terminates. At time t6, the incrementing Count value meets or exceeds the digital value of the coefficient data X_{N}, and the word line signal pulse on the negative word line WL<N>− terminates. At time t7, the Start signal is deasserted and the Count value is reset. Additionally, the analog signals Y₁₊ to Y_{M+} on the positive bit lines BL<1>+ to BL<M>+ (selected by the column select circuit) are sampled for analog-to-digital conversion and the first (positive) elaboration of the in-memory compute operation ends.

At time t8, the column select circuitry of the column processing circuit 120 selects the negative bit lines BL<A>− through the multiplexing in connection with performing the second (negative) elaboration of the in-memory compute operation. We again assume here the example discussed above and shown in FIG. 4 where there is a simultaneous selection of all rows of groups 115_{AB} of memory cells 114 in response to the non-zero coefficient data, and the simultaneous actuation in response to assertion of the Start_{B} signals at time t9 of the word lines WL<1>+, WL<2>+corresponding to the positive feature or coefficient data X₁, X₂ with pulsed word line signals and the word line WL<N>− corresponding to the negative feature or coefficient data X_{N} with a pulsed word line signal. Also at time t9, the previously reset Count value begins to increment. At time t10, the incrementing Count value meets or exceeds the digital value of the coefficient data X₁, and the word line signal pulse on the positive word line WL<1>+ terminates. At time t11, the incrementing Count value meets or exceeds the digital value of the coefficient data X₂, and the word line signal pulse on the positive word line WL<2>+terminates. At time t12, the incrementing Count value meets or exceeds the digital value of the coefficient data X_{N}, and the word line signal pulse on the negative word line WL<N>− terminates. At time t13, the Start signal is deasserted and the Count value is reset. Additionally, the analog signals Y₁₋ to Y_{M-} on the negative bit lines BL<1>− to BL<M>− (selected by the column select circuit) are sampled for analog-to-digital conversion and the second (negative) elaboration of the in-memory compute operation ends. At time t14, the overall in-memory compute operation ends.

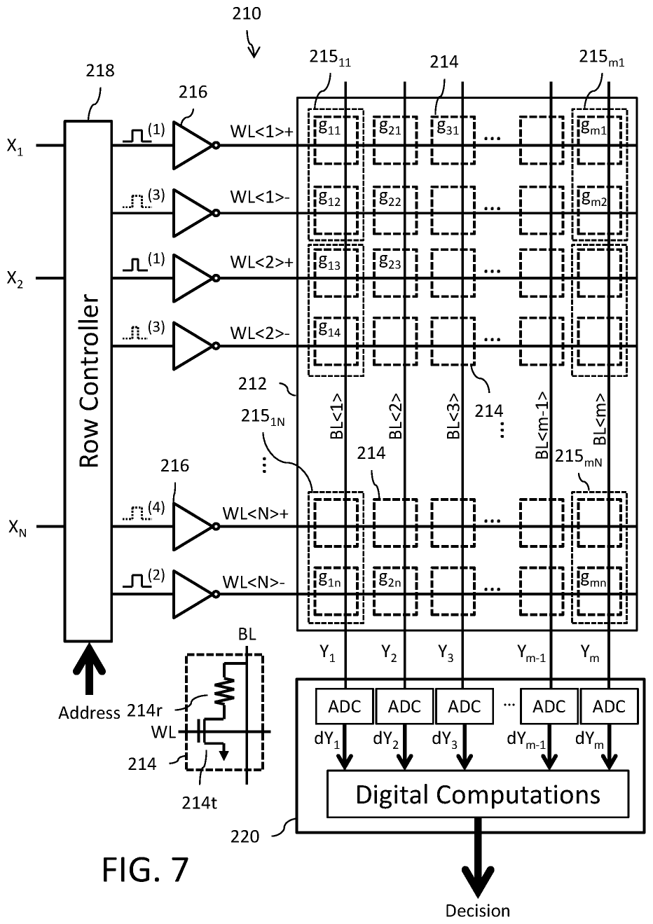

Reference is now made to FIG. 7 which shows a schematic diagram of an in-memory computation circuit 210. The circuit 210 utilizes a memory array 212 formed by a plurality of memory cells 214 arranged in a matrix format having m columns and n rows. The array 212 is arranged to include groups 215₁₁ to 215_{mN} of memory cells 114, wherein each group 215_{aB} includes two memory cells arranged in a 1×2 matrix, where a is an integer from 1 to m and B is an integer from 1 to N. With this arrangement, there are N rows of groups 215_{aB} and m columns of groups 215_{aB} (where N=n/2).

Each group 215_{aB} of memory cells 214 stores a signed computational weight (also referred to as kernel data) for an in-memory compute operation. Each memory cell 214 can be programmed to store a bit of data g_{ab}, where a is an integer from 1 to m and b is an integer from 1 to n, for the signed computational weight of the group 215_{aB}. Each bit of data has either a logic “1” or a logic “0” value which is represented, for example, by a programmable transconductance in the memory cell 214. A signed computational weight of “+1” for a given group 215_{aB} is represented by programming logic “1” in an upper memory cell (for example, see g₁₁=1 of group 215₁₁), and programming logic “0” in a lower memory cell (for example, see g₁₂=0 of group 215₁₁) as illustrated here:

$$[ \begin{matrix}1 \\ 0\end{matrix} ] ,$$

also referred to in the art as a single entry matrix. A signed computational weight of “−1” for a given group 215_{aB} is represented by programming logic “0” in the upper memory cell (for example, see g₁₁=0 of group 215₁₁), and programming logic “1” in a lower memory cell (for example, see g₁₂=1 of group 215¹¹) as also referred to in the art as a single entry matrix. A signed computational illustrated here:

$$[ \begin{matrix}0 \\ 1\end{matrix} ] ,$$

weight of “0” for a given group 215_{aB} is represented by programming logic “0” in both memory cells (for example, see g₁₁=0, g₁₂=0 of group 215₁₁) as illustrated here:

$$[ \begin{matrix}0 \\ 0\end{matrix} ] ,$$

also referred to in the art as a zero matrix.

In an embodiment of the memory array 212, each memory cell 214 comprises a phase change memory (PCM) cell formed by a select circuit (MOSFET transistor, BJT transistor, diode device, etc.) 214t operating as a switching element and a variable resistive element 214r providing a programmable transconductance. In the case of a MOSFET transistor for the select circuit 214t, the control node (gate) of the MOSFET transistor is connected to the word line WL. The source-drain path of the MOSFET transistor is connected in series with the variable resistive element 214r between the bit line BL and a reference node (for example, a source line or ground). More specifically, a drain of the MOSFET transistor is connected to a first terminal of the variable resistive element 214r, the source of the MOSFET transistor is connected to the reference node, and the second terminal of the variable resistive element 214r is connected to the bit line BL.

As is well known to those skilled in the art, a PCM-type memory cell 214 is configured to store data using a phase change material (such as a chalcogenide) that is capable of stably transitioning between amorphous and crystalline phases according to an amount of heat transferred thereto. The amorphous and crystalline phases exhibit two or more distinct resistances (corresponding to the variable resistive element 214r), in other words two or more distinct transconductances, which are used to distinguish two or more distinct logic states programmable into the memory cell. The amorphous phase exhibits a relatively higher resistance (i.e., a lower transconductance) and thus the current sunk from the bit line BL by the memory cell programmed in this state when selected by assertion of the word line signal at the gate of the select circuit 214t is relatively smaller. Conversely, the crystalline phase exhibits a relatively lower resistance (i.e., a higher transconductance) and thus the current sunk from the bit line BL by the memory cell programmed in this state when selected by assertion of the word line signal at the gate of the select circuit 214t is relatively larger.

In an embodiment for a specific, but non-limiting, example for two distinct logic states: the amorphous phase may represent programming of the memory cell to logic “0” (or reset state) for the associated coefficient weight and the crystalline phase may represent programming of the memory cell to logic “1” (or set state) for the associated coefficient weight.

It will be understood that other memory cell types could instead be used for the array 212. For example, magnetoresistive random access memory (MRAM) cells or resistive random access memory (RRAM) cells could be used. The memory cell may alternatively comprise a static random access memory (SRAM) cell.

Each memory cell 214 includes a word line WL and a bit line BL. The memory cells 214 in a common row of the matrix are connected to each other through a common word line WL. The groups 215_{aB} of memory cells 214 in a common row of groups 215_{aB} are connected to each other through a positive word line WL<B>+ and a negative word line WL<B>− (which form a word line pair for the common row of groups 215_{aB}). More specifically, the positive word line WL<B>+ is connected to the upper memory cell in the 1×2 matrix for the group (for example, see WL<1>+ for g₁₁ of group 215₁₁), while the negative word line WL<B>− is connected to the lower memory cell in the 1×2 matrix for the group (for example, see WL<1>− for g₁₂ of group 215₁₁).

The memory cells 214 in a common column of the matrix are connected to each other through a common bit line BL. The groups 215_{aB} of memory cells 214 in a common column of groups 215_{aB} are connected to each other through a bit line BL<a>. More specifically, the bit line BL<a> is connected to the two memory cells in the 1×2 matrix for the group (for example, see BL<1> for g₁₁ and g₁₂ of group 215₁₁).

Each word line WL is driven by a word line driver circuit 216 with a pulsed word line signal generated by a row controller circuit 218. The word line driver circuit 216 may be implemented as a CMOS driver circuit (for example, a series connected p-channel and n-channel MOSFET transistor pair forming a logic inverter circuit).

The row controller circuit 218 receives the signed feature or coefficient data X₁ to X_{N} for the in-memory compute operation. The row controller circuit 218 also receives an address signal (Address) for the in-memory compute operation and in response thereto selectively loads the signed feature or coefficient data X₁ to X_{N} for association with the rows of groups 215_{AB} of memory cells 214 which are to be simultaneously selected in parallel during each elaboration of the analog in-memory compute operation. During the simultaneous access for a given elaboration, only one word line of each word line pair (WL<B>+ or WL<B>−) is actuated with a pulsed word line signal The actuated one word line of the word line pair is selected based on: a) which of the first (positive) or second (negative) elaborations is being performed, and b) the logic state of the sign bit of the feature or coefficient data X_{B}. For example, consider the following cases: (1) if the first (positive) elaboration is being performed and the sign bit is logic 0, indicative of a positive coefficient data value, then the positive word line WL<B>+ is asserted; (2) if the first (positive) elaboration is being performed and the sign bit is logic 1, indicative of a negative coefficient data value, then the negative word line WL<B>− is asserted; (3) if the second (negative) elaboration is being performed and the sign bit is logic 0, indicative of a positive coefficient data value, then the negative word line WL<B>− is asserted; and (4) if the second (negative) elaboration is being performed and the sign bit is logic 1, indicative of a negative coefficient data value, then the positive word line WL<B>+ is asserted. The row controller circuit 218 still further controls, for each corresponding actuated word line, the width (i.e., the on time TON) of the generated pulsed word line signal. This functionality is a form of a pulse width modulation (PWM) control for the applied word line signals dependent on the digital value of the received signed feature or coefficient data X_{B}.

In an embodiment, the signed feature or coefficient data X_{B} is provided in a multi-bit signed binary format, with a 4-bit example as set forth in the following table:

| Decimal | Binary | Decimal | Binary |
|---|---|---|---|
| 0 | 0000 | 0 | 1000 |
| +1 | 0001 | −1 | 1001 |
| +2 | 0010 | −2 | 1010 |
| +3 | 0011 | −3 | 1011 |
| +4 | 0100 | −4 | 1100 |
| +5 | 0101 | −5 | 1101 |
| +6 | 0110 | −6 | 1110 |
| +7 | 0111 | −7 | 1111 |

The use of a 4-bit format for the signed feature or coefficient data X_{B} is just an example, it being understood that the signed feature or coefficient data X_{B} can use any selected number of bits depending on the computation application.

It will be noted that the most significant bit of the signed binary feature or coefficient data X_{B} provides the sign bit (logic 0 is positive, logic 1 is negative) used to control selection of the positive (WL<B>+) or negative (WL<B>−) word line of the word line pair dependent on the positive/negative elaboration, while the remaining less significant bits provide the value specifying the pulse width duration for the word line signal applied to that selected word line of the word line pair during each elaboration.

FIG. 7 illustrates, by way of example only, the simultaneous selection of all rows of groups 215_{aB} of memory cells 214 in response to non-zero coefficient data, and further illustrates, by way of example only with solid word line signal pulses (with adjacent parenthetical numbers identifying the particular case as noted above), the positive elaboration of the in-memory compute operation including the simultaneous actuation of certain positive word lines (WL<1>+ and WL<2>+, for example) corresponding to positively signed feature or coefficient data (X₁ and X₂, for example) with pulsed word line signals having pulse widths set by the digital value of the corresponding coefficient data (case (1)), along with the simultaneous actuation of certain negative word lines (WL<N>−, for example) corresponding to negatively signed feature or coefficient data (X_{N}, for example) with pulsed word line signals having pulse widths set by the digital value of the corresponding coefficient data (case (2)).

FIG. 7 further illustrates, by way of example only, the simultaneous selection of all rows of groups 215_{aB} of memory cells 214 in response to non-zero coefficient data, and further illustrates, by way of example only with dotted word line signal pulses (with adjacent parenthetical numbers identifying the particular case as noted above), the negative elaboration of the in-memory compute operation including the simultaneous actuation of certain negative word lines (WL<1>− and WL<2>−, for example) corresponding to positively signed feature or coefficient data (X₁ and X₂, for example) with pulsed word line signals having pulse widths set by the digital value of the corresponding coefficient data (case (3)), along with the simultaneous actuation of certain positive word lines (WL<N>+−, for example) corresponding to negatively signed feature or coefficient data (X_{N}, for example) with pulsed word line signals having pulse widths set by the digital value of the corresponding coefficient data (case (4)).

It will, of course, be understood that the positive/negative elaborations for the analog in-memory compute operation may instead utilize a simultaneous selection of fewer than all rows of groups 215_{aB} of memory cells 214 (through either Address signal selection or through a zero value for the coefficient data X_{B}).

The analog signal Yₐ developed during the elaboration on each bit line BL<a> is dependent on the logic state of the bit of data gab for the signed computational weight stored in the memory cells 214 of the column and the widths of the pulsed word line signals applied to the word lines WL for those memory cells 214. More specifically, it will be understood that each memory cell 214 contributes a bit line BL discharge current during the elaboration that is proportional to X_{B}×g_{ab}. So, in the example shown in FIG. 7 where the (solid) word line signals are simultaneously applied to the word lines WL<1>+, WL<2>+, . . . , WL<N>− during the first (positive) elaboration of the in-memory compute operation, the analog signal Y₁ developed on the bit line BL<1> is proportional to the sum of discharge currents due to X₁×g₁₁, 0×g₁₂, X₂×g₁₃, 0×g₁₄, . . . , 0×g₁ₙ₋₁ and X_{N}×g₁ₙ. Conversely, where the (dotted) word line signals are simultaneously applied to the word lines WL<1>−, WL<2>−, . . . , WL<N>+ during the second (negative) elaboration, the analog signal Y₁ developed on the same bit line BL<1> is proportional to the sum of discharge currents due to 0×g₁₁, X₁×g₁₂, 0×g₁₃, X₂×g₁₄, . . . , X_{N}×g₁ₙ₋₁ and 0×g₁ₙ. The overall result of the in-memory compute operation is a function of the difference between analog signals developed during the first and second elaborations.

Let's assume now, for example only, some specific signed computational weights for the groups 215_{aB} of memory cells 214 in this column of groups. Group 215₁₁ is programmed with weight of −1 which is represented by

$$[ \begin{matrix}0 \\ 1\end{matrix} ] .$$

Group 115₁₂ is programmed with weight of 0 which is represented by

$$[ \begin{matrix}0 \\ 0\end{matrix} ] .$$

Group 115_{IN} is programmed with weight of +1 which is represented by

$$[ \begin{matrix}1 \\ 0\end{matrix} ] .$$

So, for this example, the analog signal Y₁ developed on the bit line BL<1>during the first (positive) elaboration is proportional to the sum of discharge currents due to X₁×0, 0×1, X₂×0, 0×0, . . . , 0×1 and X_{N}×0; which would result in zero discharge currents on the bit line BL<1>. The analog signal Y₁ developed on the bit line BL<1> during the second (negative) elaboration is proportional to the sum of discharge currents due to 0×0, X₁×1, 0×0, X₂×0, . . . , X_{N}×1 and 0×0; which results in a sum of discharge currents due to X₁×1, . . . , and X_{N}×1 on the bit line BL<1>.

A column processing circuit 220 senses and samples during each of the first and second elaborations of the in-memory compute operation the analog signal Yₐ on each bit line BL<a> for the m columns and converts the analog signal to a corresponding digital signal dYₐ using analog-to-digital converter circuitry. Although FIG. 7 illustrates that one analog-to-digital converter (ADC) is provided for each column, it will be understood that ADC resources in the column processing circuit 220 could instead be shared by multiple columns using time division multiplexing. The column processing circuit 220 further includes digital signal processing circuitry for storing the resulting digital signals dYₐ for the two elaborations and performing digital computations and calculations on the digital signals dYₐ to generate a decision output for the in-memory compute operation. The further computations and calculations performed may include subtracting the digital signal dY_{A} for the negative elaboration from the digital signal dY_{A} for the positive elaboration.

Although not explicitly shown in FIG. 7, it will be understood that the circuit 210 further includes conventional row decode, column decode, and read-write circuits known to those skilled in the art for use in connection with writing bits of data (for example, the computational weight data) to, and reading bits of data from, the memory cells 214 of the memory array 212. This operation is referred to as a conventional memory access mode and is distinguished from the analog in-memory compute operation discussed above.

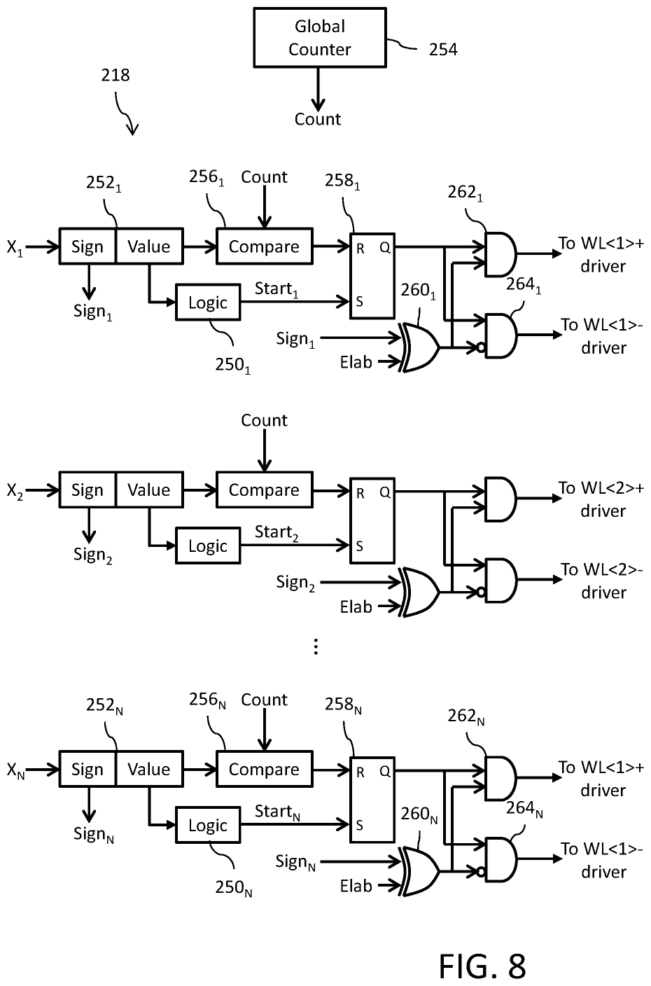

*Reference is now made to FIG. 8 which shows a circuit diagram for the row controller 218. A latch circuit 252_{B} is provided for each row of groups 215_{aB} of memory cells 214 to latch the corresponding sign and value of the signed digital value of the coefficient data X_{B}. A logic circuit 250_{B} is provided for each row of groups 215_{aB} of memory cells 214. The logic circuits 250₁ to 250_{N} assert a start signal (Start_{B}), for example in response to a global start signal, at a beginning of each elaboration of the first (positive) and second (negative) elaborations of the in-memory compute operation. The generation of this start signal may, for example, be dependent on the corresponding signed digital value of the coefficient data X_{B} having a non-zero value for the analog in-memory compute operation. A global counter circuit 254 increments a count value (Count) starting from a zero reset at the beginning of each elaboration for the in-memory compute operation, wherein the elaboration ends when the Count reached a maximum value. A compare circuit 256_{B} for each row of groups 215_{aB} of memory cells 214 is coupled to the latch circuit 252_{B} and compares the count value Count to the latched digital value of the coefficient data X_{B}. The output of the compare circuit 256_{B} is asserted when the count value Count meets or exceeds the latched digital value. A set-reset latch circuit 258_{B} has a set (S) input coupled to receive the Start_{B} signal output from the logic circuit 250_{B} and a reset (R) input coupled to receive the output of the compare circuit 256_{B}. A combinational logic circuit 260_{B} logically combines the sign bit Sign_{B} from the latch circuit 252_{B} and an elaboration indicator signal (Elab). The toggling logic state of the elaboration indicator signal Elab indicates whether the first (positive) elaboration is being performed (logic 1) or the second (negative) elaboration is being performed (logic 0). In an embodiment, the combinational logic circuit 260_{B} is a logic exclusive OR (XOR) gate. A combinational logic circuit 262_{B} logically combines the output (Q) of the set-reset latch circuit 258_{B} and the output of the combinational logic circuit 260_{B} to generate the pulsed word line signal for application to the driver circuit 216 of the positive word line WL<B>+ . A combinational logic circuit 264_{B} logically combines the output (Q) of the set-reset latch circuit 258_{B} and the logical inverse of the output of the combinational logic circuit 260_{B} to generate the pulsed word line signal for application to the driver circuit 216 of the negative word line WL<B>−. In an embodiment, the combinational logic circuits 262_{B} and 264_{B} are logic AND gates.

Operation of the circuitry within the row controller 218 is as follows: At the beginning of the in-memory compute operation, decoding of the address signal Address is used to selectively load the digital values of the coefficient data X₁ to X_{N} to be latched by the latch circuits 252₁ to 252_{N}, and the global counter 254 is reset. If the coefficient data is non-zero, there is a selection of the row of groups 215_{aB} of memory cells 214, and the start signal Start_{B} output of the logic circuit 250_{B} is asserted logic high at the beginning of each elaboration of the first (positive) and second (negative) elaborations, and the set-reset latch circuit 258_{B} is set with its output Q logic high. The logic state of the toggling elaboration indicator signal Elab indicates whether the first (positive) elaboration is being performed (logic 1) or the second (negative) elaboration is being performed (logic 0). Consideration is now made to each of the four cases noted above. Case (1): if the sign bit Signs is logic 0, indicating that the digital value of the coefficient data X_{B} is positive, and the elaboration indicator signal Elab is logic 1, indicating the first (positive) elaboration of the in-memory compute operation is being performed, the inputs of the XOR gate 260_{B} are opposite logic and the output of the XOR gate 260_{B} is logic high. Here, both inputs of the AND gate 262_{B} are logic high and the output of the AND gate 262_{B} transitions to logic high to provide the leading edge of the word line signal pulse on the positive word line WL<B>+. Case (2): if the sign bit Signs is logic 1, indicating that the digital value of the coefficient data X_{B} is negative, and the elaboration indicator signal Elab is logic 1, indicating the first (positive) elaboration of the in-memory compute operation is being performed, both inputs of the XOR gate 260_{B} are logic high and the output of the XOR gate 260_{B} is logic low. Here, both inputs of the AND gate 264_{B} are logic high and the output of the AND gate 264_{B} transitions to logic high to provide the leading edge of the word line signal pulse on the negative word line WL<B>−. Case (3): if the sign bit Signs is logic 0, indicating that the digital value of the coefficient data X_{B} is positive, and the elaboration indicator signal Elab is logic 0, indicating the second (negative) elaboration of the in-memory compute operation is being performed, both inputs of the XOR gate 260_{B} are logic low and the output of the XOR gate 260_{B} is logic low. Here, both inputs of the AND gate 264_{B} are logic high and the output of the AND gate 264_{B} transitions to logic high to provide the leading edge of the word line signal pulse on the negative word line WL<B>−. Case (4): if the sign bit Sign_{B} is logic 1, indicating that the digital value of the coefficient data X_{B} is negative, and the elaboration indicator signal Elab is logic 0, indicating the second (negative) elaboration of the in-memory compute operation is being performed, the inputs of the XOR gate 260_{B} are opposite logic and the output of the XOR gate 260_{B} is logic high. Here, both inputs of the AND gate 262_{B} are logic high and the output of the AND gate 262_{B} transitions to logic high to provide the leading edge of the word line signal pulse on the positive word line WL<B>+. The global counter 254 then begins incrementing the Count value. When the incrementing Count value meets or exceeds the digital value of the coefficient data X_{B} latched by the latch circuit 252_{B}, the output of the compare circuit 256_{B} is asserted logic high, and the set-reset latch circuit 258_{B} is reset with its output Q logic low. This logic low output is applied to both AND gates 262_{B} and 264_{B}, and whichever output of those AND gates is logic high (corresponding to assertion of the word line signal pulse) will transition to logic low to provide the trailing edge of the word line signal pulse. The pulse width (i.e., the on time T_{ON}) of the generated pulsed word line signal is thus dependent on the amount of time needed for the incrementing Count value to reach the digital value of the coefficient data X_{B}. When the Count reaches its maximum value, the given elaboration ends.

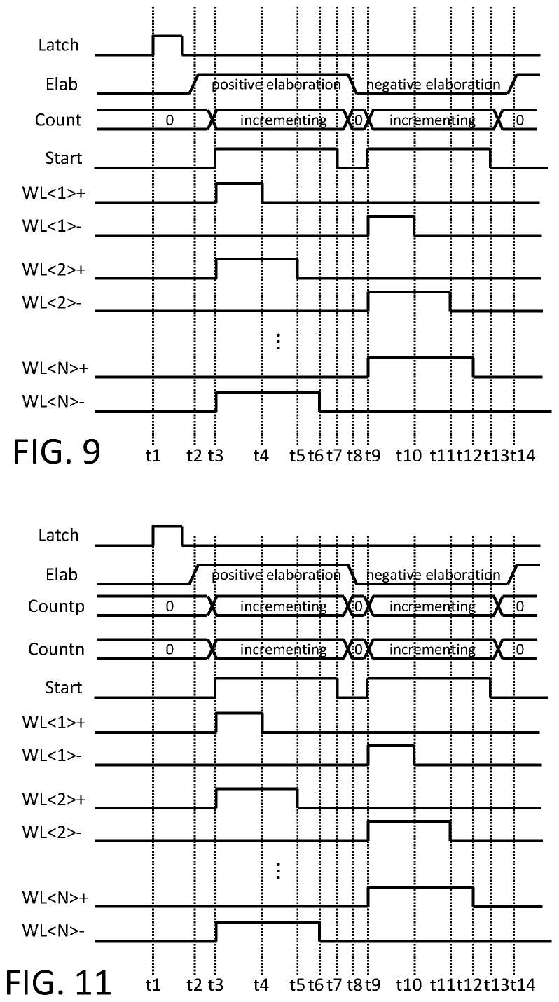

Reference is now made to FIG. 9 which shows a simplified timing diagram for operation of the circuit 210 in connection with one overall in-memory compute operation including two separate elaborations and use of the circuit 218. At time t1, a latch control signal is asserted to cause the latch circuits 252₁ to 252_{N} to latch the signed digital values of the coefficient data X₁ to X_{N}, and the overall in-memory compute operation begins. At time t2, the elaboration indicator signal Elab toggles to logic 1 in connection with starting the first (positive) elaboration of the in-memory compute operation. We assume here the example discussed above and shown in FIG. 7 where, during the first (positive) elaboration of the in-memory compute operation, there is a simultaneous selection of all rows of groups 215_{aB} of memory cells 214 in response to the non-zero coefficient data, and the simultaneous actuation in response to assertion of the Starts signals at time t3 of the word lines WL<1>+, WL<2>+ corresponding to the positive feature or coefficient data X₁, X₂ with pulsed word line signals (case (1)) and also the word line WL<N>− corresponding to the negative feature or coefficient data X_{N} with a pulsed word line signal (case (2)). Also at time t3, the previously reset Count value begins to increment. At time t4, the incrementing Count value meets or exceeds the digital value of the coefficient data X₁, and the word line signal pulse on the positive word line WL<1>+ terminates. At time t5, the incrementing Count value meets or exceeds the digital value of the coefficient data X₂, and the word line signal pulse on the positive word line WL<2>+ terminates. At time t6, the incrementing Count value meets or exceeds the digital value of the coefficient data X_{N}, and the word line signal pulse on the negative word line WL<N>− terminates. At time t7, the Start signal is deasserted and the Count value is reset. Additionally, the analog signals Y₁ to Yₘ on the bit lines BL<1> to BL<m> are sampled for analog-to-digital conversion. At time t8, the elaboration indicator signal Elab toggles to logic 0 in connection with ending the first (positive) elaboration of the in-memory compute operation.

The toggling of the elaboration indicator signal Elab to logic 0 at time t8 additionally starts the second (negative) elaboration of the in-memory compute operation. We assume here the example discussed above and shown in FIG. 7 where, during the second (negative) elaboration of the in-memory compute operation, there is a simultaneous selection of all rows of groups 215_{aB} of memory cells 214 in response to the non-zero coefficient data, and the simultaneous actuation in response to assertion of the Start_{B} signals at time t9 of the word lines WL<1>−, WL<2>− corresponding to the positive feature or coefficient data X₁, X₂ with pulsed word line signals (case (3)) and also the word line WL<N>+ corresponding to the negative feature or coefficient data X_{N} with a pulsed word line signal (case (4)). Also at time t9, the previously reset Count value begins to increment. At time t10, the incrementing Count value meets or exceeds the digital value of the coefficient data X₁, and the word line signal pulse on the negative word line WL<1>− terminates. At time t11, the incrementing Count value meets or exceeds the digital value of the coefficient data X₂, and the word line signal pulse on the negative word line WL<2>− terminates. At time t12, the incrementing Count value meets or exceeds the digital value of the coefficient data X_{N}, and the word line signal pulse on the positive word line WL<N>+ terminates. At time t13, the Start signal is deasserted and the Count value is reset. Additionally, the analog signals Y₁ to Yₘ on the bit lines BL<1> to BL<m> are sampled for analog-to-digital conversion. At time t14, the elaboration indicator signal Elab toggles to logic 1 in connection with both ending the second (negative) elaboration of the in-memory compute operation and ending the overall in-memory compute operation.

An advantage of the FIG. 7 implementation is that the signed computational weight for the in-memory compute operation is coded on two memory cells 214 forming the group 215_{aB} with a 1×2 matrix configuration, while the FIG. 4 implementation utilizes four memory cells 114 forming the group 115_{AB} with a 2×2 matrix configuration. There is accordingly a 2× memory reduction for the array 212 compared to the array 112 (or there is a 2× increase in weight storage capacity for the array 212 compared to the array 112).

A drawback of the circuit implementation for the row controller 218 shown in FIG. 8 is that it cannot handle signed computational weight in a 2's complement binary format. For example, the signed feature or coefficient data X_{B} may be provided in a multi-bit 2's complement binary format, with 4-bits by example as set forth in the following table:

| Decimal | Binary | Decimal | Binary |
|---|---|---|---|
| 0 | 0000 | −8 | 1000 |
| +1 | 0001 | −7 | 1001 |
| +2 | 0010 | −6 | 1010 |
| +3 | 0011 | −5 | 1011 |
| +4 | 0100 | −4 | 1100 |
| +5 | 0101 | −3 | 1101 |
| +6 | 0110 | −2 | 1110 |
| +7 | 0111 | −1 | 1111 |

The use of a 4-bit format for the signed feature or coefficient data X_{B} is just an example, it being understood that the signed feature or coefficient data X_{B} can use any selected number of bits depending on the computation application.

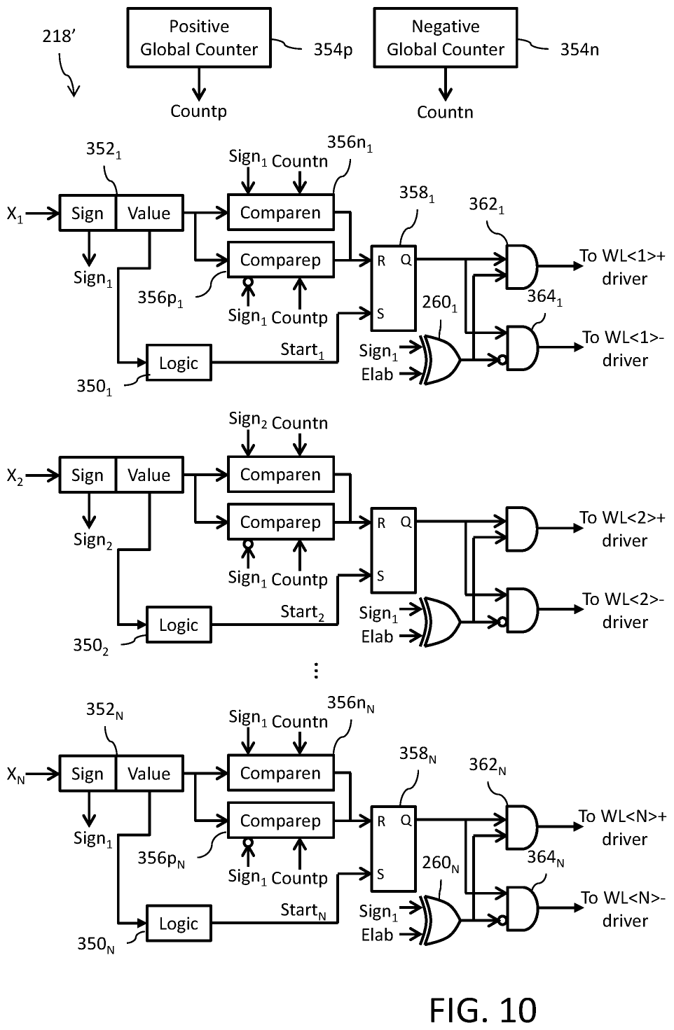

It will be noted that the most significant bit of the 2's complement binary signed feature or coefficient data X_{B} provides the sign bit (logic 0 is positive, logic 1 is negative) used to control selection of the positive (WL<B>+) or negative (WL<B>−) word line of the word line pair dependent on the positive/negative elaboration, while the remaining less significant bits provide the value specifying the pulse width duration for the word line signal applied to that selected word line of the word line pair during each elaboration. However, because the range of positive values (0 to +7) is different from the range of negative values (0 to −8), the circuit implementation for the row controller 218 shown in FIG. 8 will not work. An alternative circuit implementation for the row controller 218′ supporting 2's complement binary signed feature or coefficient data X_{B} is shown in FIG. 10.

A latch circuit 352_{B} is provided for each row of groups 215_{aB} of memory cells 214 to latch the corresponding sign and value of the signed digital value of the coefficient data X_{B}. A logic circuit 350_{B} is provided for each row of groups 215_{aB} of memory cells 214. The logic circuits 350₁ to 350_{N} assert a start signal (Start_{B}) at a beginning of each elaboration of the first (positive) and second (negative) elaborations of the in-memory compute operation. The generation of this start signal may, for example, be dependent on the corresponding signed digital value of the coefficient data X_{B} having a non-zero value for the analog in-memory compute operation. A positive global counter circuit 354p increments a positive count value (Count0) starting from a zero reset at the beginning of each elaboration for the in-memory compute operation. A negative global counter circuit 354n increments a negative count value (Countn) starting from a zero reset at the beginning of each elaboration for the in-memory compute operation. The elaboration ends when the Countn reaches a maximum value. A positive compare circuit 356p_{B} for each row of groups 215_{aB} of memory cells 214 is coupled to the latch circuit 352_{B}. The positive compare circuit 356p_{B} is enabled in response to a logic low state of the sign bit Sign_{B} (indicating that the signed digital value of the coefficient data X_{B} is positive) and compares the positive count value Countp to the latched digital value of the coefficient data X_{B}. A negative compare circuit 356_{nB} for each row of groups 215_{aB} of memory cells 214 is coupled to the latch circuit 352_{B}. The negative compare circuit 236n_{B} is enabled in response to a logic high state of the sign bit Sign_{B} (indicating that the signed digital value of the coefficient data X_{B} is negative) and compares the negative count value Countn to the latched digital value of the coefficient data X_{B}. The signal output from the enabled one of compare circuits 356p_{B} and 356n_{B} is asserted when the count value Countp or Countn meets or exceeds the latched digital value. A set-reset latch circuit 358B has a set (S) input coupled to receive the Starts signal output from the logic circuit 350_{B} and a reset (R) input coupled to receive the output of the enabled one of the compare circuits 356p_{B} or 356n_{B}. A combinational logic circuit 360_{B} logically combines the sign bit Signs from the latch circuit 352_{B} and an elaboration indicator signal (Elab). The toggling logic state of the elaboration indicator signal Elab indicates whether the first (positive) elaboration is being performed (logic 1) or the second (negative) elaboration is being performed (logic 0). In an embodiment, the combinational logic circuit 360_{B} is a logic exclusive OR (XOR) gate. A combinational logic circuit 362_{B} logically combines the output (Q) of the set-reset latch circuit 358_{B} and the output of the combinational logic circuit 360_{B} to generate the pulsed word line signal for application to the driver circuit 216 of the positive word line WL<B>+. A combinational logic circuit 364_{B} logically combines the output (Q) of the set-reset latch circuit 358_{B} and the logical inverse of the output of the combinational logic circuit 360_{B} to generate the pulsed word line signal for application to the driver circuit 216 of the negative word line WL<B>−. In an embodiment, the combinational logic circuits 362_{B} and 364_{B} are logic AND gates.

Operation of the circuitry within the row controller 218′ is as follows: At the beginning of the in-memory compute operation, decoding of the address signal Address is used to selectively load the digital values of the coefficient data X₁ to X_{N} to be latched by the latch circuits 352₁ to 352_{N}, and the global counters 354p and 354n are reset. If the coefficient data is non-zero, there is a selection of the row of groups 215_{aB} of memory cells 214, and the start signal Starts output of the logic circuit 350_{B} is asserted logic high at the beginning of each elaboration of the first (positive) and second (negative) elaborations, and the set-reset latch circuit 358_{B} is set with its output Q logic high. The logic state of the toggling the elaboration indicator signal Elab indicates whether the first (positive) elaboration is being performed (logic 1) or the second (negative) elaboration is being performed (logic 0). Consideration is now made to each of the four cases noted above. Case (1): if the sign bit SignB is logic 0, indicating that the digital value of the coefficient data X_{B} is positive, and the elaboration indicator signal Elab is logic 1, indicating the first (positive) elaboration of the in-memory compute operation is being performed, the positive compare circuit 356p_{B} is enabled and the inputs of the XOR gate 360_{B} are opposite logic and the output of the XOR gate 360_{B} is logic high. Here, both inputs of the AND gate 362_{B} are logic high and the output of the AND gate 362_{B} transitions to logic high to provide the leading edge of the word line signal pulse on the positive word line WL<B>+. Case (2): if the sign bit Sign_{B} is logic 1, indicating that the digital value of the coefficient data X_{B} is negative, and the elaboration indicator signal Elab is logic 1, indicating the first (positive) elaboration of the in-memory compute operation is being performed, the negative compare circuit 356n_{B} is enabled and both inputs of the XOR gate 360_{B} are logic high and the output of the XOR gate 360_{B} is logic low. Here, both inputs of the AND gate 364_{B} are logic high and the output of the AND gate 364_{B} transitions to logic high to provide the leading edge of the word line signal pulse on the negative word line WL<B>−. Case (3): if the sign bit Sign_{B} is logic 0, indicating that the digital value of the coefficient data X_{B} is positive, and the elaboration indicator signal Elab is logic 0, indicating the second (negative) elaboration of the in-memory compute operation is being performed, the positive compare circuit 356p_{B} is enabled and both inputs of the XOR gate 360_{B} are logic low and the output of the XOR gate 360_{B} is logic low. Here, both inputs of the AND gate 364_{B} are logic high and the output of the AND gate 364_{B} transitions to logic high to provide the leading edge of the word line signal pulse on the negative word line WL<B>−. Case (4): if the sign bit SignB is logic 1, indicating that the digital value of the coefficient data X_{B} is negative, and the elaboration indicator signal Elab is logic 0, indicating the second (negative) elaboration of the in-memory compute operation is being performed, the negative compare circuit 356n_{B} is enabled and the inputs of the XOR gate 360_{B} are opposite logic and the output of the XOR gate 360_{B} is logic high. Here, both inputs of the AND gate 362_{B} are logic high and the output of the AND gate 362_{B} transitions to logic high to provide the leading edge of the word line signal pulse on the positive word line WL<B>+. The global counters 354p and 354n then begin incrementing the Countp and Countn values. For cases (1) and (3) where the positive compare circuit 356p_{B} is enabled by the logic low sign bit Sign_{B}, when the incrementing Countp value meets or exceeds the digital value of the coefficient data X_{B} latched by the latch circuit 352_{B}, the output of the compare circuit 356_{B} is asserted logic high, and the set-reset latch circuit 358_{B} is reset with its output Q logic low. This logic low output is applied to both AND gates 362_{B} and 364_{B}, and whichever output of those AND gates is logic high (corresponding to assertion of the word line signal pulse) will transition to logic low to provide the trailing edge of the word line signal pulse. The pulse width (i.e., the on time T_{ON}) of the generated pulsed word line signal is thus dependent on the amount of time needed for the incrementing Countp value to reach the digital value of the coefficient data X_{B}. For cases (2) and (4) where the negative compare circuit 356n_{B} is enabled by the logic high sign bit Sign_{B}, when the incrementing Countn value meets or exceeds the digital value of the coefficient data X_{B} latched by the latch circuit 352_{B}, the output of the compare circuit 356_{B} is asserted logic high, and the set-reset latch circuit 358_{B} is reset with its output Q logic low. This logic low output is applied to both AND gates 362_{B} and 364_{B}, and whichever output of those AND gates is logic high (corresponding to assertion of the word line signal pulse) will transition to logic low to provide the trailing edge of the word line signal pulse. The pulse width (i.e., the on time T_{ON}) of the generated pulsed word line signal is thus dependent on the amount of time needed for the incrementing Countn value to reach the digital value of the coefficient data X_{B}. When the Countn reaches its maximum value, the given elaboration ends.

Reference is now made to FIG. 11 which shows a simplified timing diagram for operation of the circuit 210 in connection with one overall in-memory compute operation including two separate elaborations and the use of the circuit 281′. At time t1, a latch control signal is asserted to cause the latch circuits 352₁ to 352_{N} to latch the signed digital values of the coefficient data X₁ to X_{N}, and the overall in-memory compute operation begins. At time t2, the elaboration indicator signal Elab toggles to logic 1 in connection with starting the first (positive) elaboration of the in-memory compute operation. We assume here the example discussed above and shown in FIG. 7 where, during the first (positive) elaboration of the in-memory compute operation, there is a simultaneous selection of all rows of groups 215_{aB} of memory cells 214 in response to the non-zero coefficient data, and the simultaneous actuation in response to assertion of the Starts signals at time t3 of the word lines WL<1>+, WL<2>+ corresponding to the positive feature or coefficient data X₁, X₂ with pulsed word line signals (case (1)) and also the word line WL<N>− corresponding to the negative feature or coefficient data X_{N} with a pulsed word line signal (case (2)). Also at time t3, the previously reset Countp and Countn values begin to increment. At time t4, the incrementing Countp value meets or exceeds the digital value of the coefficient data X₁, and the word line signal pulse on the positive word line WL<1>+ terminates. At time t5, the incrementing Countp value meets or exceeds the digital value of the coefficient data X₂, and the word line signal pulse on the positive word line WL<2>+ terminates. At time t6, the incrementing Countn value meets or exceeds the digital value of the coefficient data X_{N}, and the word line signal pulse on the negative word line WL<N>− terminates. At time t7, the Start signal is deasserted and the Countp and Countn values are reset. Additionally, the analog signals Y₁ to Yₘ on the bit lines BL<1> to BL<m> are sampled for analog-to-digital conversion. At time t8, the elaboration indicator signal Elab toggles to logic 0 in connection with ending the first (positive) elaboration of the in-memory compute operation.

The toggling of the elaboration indicator signal Elab to logic 0 at time t8 additionally starts the second (negative) elaboration of the in-memory compute operation. We assume here the example discussed above and shown in FIG. 7 where, during the second (negative) elaboration of the in-memory compute operation, there is a simultaneous selection of all rows of groups 215_{aB} of memory cells 214 in response to the non-zero coefficient data, and the simultaneous actuation in response to assertion of the Starts signals at time t9 of the word lines WL<1>−, WL<2>− corresponding to the positive feature or coefficient data X₁, X₂ with pulsed word line signals (case (3)) and also the word line WL<N>+ corresponding to the negative feature or coefficient data X_{N} with a pulsed word line signal (case (4)). Also at time t9, the previously reset Countp and Countn values begin to increment. At time t10, the incrementing Countp value meets or exceeds the digital value of the coefficient data X₁, and the word line signal pulse on the negative word line WL<1>− terminates. At time t11, the incrementing Countp value meets or exceeds the digital value of the coefficient data X₂, and the word line signal pulse on the negative word line WL<2>− terminates. At time t12, the incrementing Countn value meets or exceeds the digital value of the coefficient data X_{N}, and the word line signal pulse on the positive word line WL<N>+ terminates. At time t13, the Start signal is deasserted and the Countp and Countn values are reset. Additionally, the analog signals Y₁ to Yₘ on the bit lines BL<1> to BL<m> are sampled for analog-to-digital conversion. At time t14, the elaboration indicator signal Elab toggles to logic 1 in connection with both ending the second (negative) elaboration of the in-memory compute operation and ending the overall in-memory compute operation.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. An in-memory computation circuit, comprising:
a memory array including a plurality of memory cells arranged in a matrix with plural rows and plural columns, wherein groups of memory cells store computational weights for an in-memory compute (IMC) operation that is performed with a first multiply and accumulate (MAC) elaboration and a second MAC elaboration, each row of groups of memory cells including a positive word line coupled to a first memory cell in each group of memory cells and a negative word line coupled to a second memory cell in each group of memory cells, and each column of groups of memory cells including a bit line coupled to the first and second memory cells of each group of memory cells;
a row controller circuit configured to receive signed coefficient data for the IMC operation and: a) generate during the first MAC elaboration a pulsed word line signal for application to the positive word line when the signed coefficient data is positive, and generate a pulsed word line signal for application to the negative word line when the signed coefficient data is negative; and b) generate during the second MAC elaboration a pulsed word line signal for application to the negative word line when the signed coefficient data is positive, and generate a pulsed word line signal for application to the positive word line when the signed coefficient data is negative; and
a column processing circuit coupled to the bit line and configured to: a) sense a first analog signal developed on the bit line during the first MAC elaboration; and b) sense a second signal developed on the bit line during the second MAC elaboration.

2. The in-memory computation circuit of claim 1, wherein the column processing circuit is further configured to process the first and second analog signals to generate a result of the IMC operation.

3. The in-memory computation circuit of claim 2, wherein the processing of the first and second analog signals to generate the result of the IMC operation comprises determining a difference between the first and second analog signals.

4. The in-memory computation circuit of claim 1, wherein the row controller circuit is further configured to identify a plurality of rows of groups of memory cells to be simultaneously selected for receiving pulsed word line signals during the first and second MAC elaborations of the IMC operation.

5. The in-memory computation circuit of claim 1, wherein the signed coefficient data for the IMC operation is in a signed binary format including a sign bit and a plurality of data bits providing a coefficient value, and wherein the row controller circuit is further configured to control a pulse width of the pulsed word line signal dependent on the coefficient value.

6. The in-memory computation circuit of claim 5, wherein the row controller circuit comprises, for each row of groups of memory cells:
a data latch configured to latch the sign bit and plurality of data bits for the signed coefficient data;
a counter circuit configured to generate an incrementing count value; and
a comparison circuit configured to compare the coefficient value specified by the latched plurality of data bits to the incrementing count value and control a trailing edge of the pulse width of the pulsed word line signal based on the comparison.

7. The in-memory computation circuit of claim 5, wherein the row controller circuit comprises, for each row of groups of memory cells:
a data latch configured to latch the sign bit and plurality of data bits for the signed coefficient data;
logic circuitry having a first input coupled to receive the sign bit, a second input coupled to receive an elaboration indication signal having a first logic state during the first MAC elaboration and having a second logic state during the second MAC elaboration, and an output configured to generate a control signal for selecting one of the positive and negative word lines for application of the pulsed word line signal.

8. The in-memory computation circuit of claim 7, further including:
a first logic gate having a first input coupled to receive the control signal, a second input configured to receive the pulsed word line signal, and an output coupled to the positive word line; and
a second logic gate having a first input coupled to receive a logical inverse of the control signal, a second input configured to receive the pulsed word line signal, and an output coupled to the negative word line.

9. The in-memory computation circuit of claim 8, further including a set-reset flip flop configured to generate the pulsed word line signal.

10. The in-memory computation circuit of claim 9, wherein a first state of the set-reset flip flop is controlled by a start of each of the first and second MAC elaborations and a second state of the set-reset flip flop is controlled by a timing circuit

11. The in-memory computation circuit of claim 10, wherein the timing circuit comprises:
a counter circuit configured to generate an incrementing count value; and
a comparison circuit configured to compare the coefficient value specified by the latched plurality of data bits to the incrementing count value and generate a signal controlling the second state based on the comparison.

12. The in-memory computation circuit of claim 1, wherein the signed coefficient data for the IMC operation is in a signed 2's complement format including a sign bit and a plurality of data bits providing a coefficient value, and wherein the row controller circuit is further configured to control a pulse width of the pulsed word line signal dependent on the coefficient value.

13. The in-memory computation circuit of claim 12, wherein the row controller circuit comprises, for each row of groups of memory cells:
a data latch configured to latch the sign bit and plurality of data bits for the signed coefficient data;
a first counter circuit configured to generate a first incrementing count value;
a second counter circuit configured to generate a second incrementing count value;
a first comparison circuit enabled by a first logic state of the sign bit to compare the coefficient value specified by the latched plurality of data bits to the first incrementing count value and control a trailing edge of the pulse width of the pulsed word line signal based on the first comparison; and
a second comparison circuit enabled by a second logic state of the sign bit to compare the coefficient value specified by the latched plurality of data bits to the second incrementing count value and control the trailing edge of the pulse width of the pulsed word line signal based on the second comparison.

14. The in-memory computation circuit of claim 12, wherein the row controller circuit comprises, for each row of groups of memory cells:
a data latch configured to latch the sign bit and plurality of data bits for the signed coefficient data;
logic circuitry having a first input coupled to receive the sign bit, a second input coupled to receive an elaboration indication signal having a first logic state during the first MAC elaboration and having a second logic state during the second MAC elaboration, and an output configured to generate a control signal for selecting one of the positive and negative word lines for application of the pulsed word line signal.

15. The in-memory computation circuit of claim 14, further including:
a first logic gate having a first input coupled to receive the control signal, a second input configured to receive the pulsed word line signal, and an output coupled to the positive word line; and
a second logic gate having a first input coupled to receive a logical inverse of the control signal, a second input configured to receive the pulsed word line signal, and an output coupled to the negative word line.

16. The in-memory computation circuit of claim 15, further including a set-reset flip flop configured to generate the pulsed word line signal.

17. The in-memory computation circuit of claim 16, wherein a first state of the set-reset flip flop is controlled by a start of each of the first and second MAC elaborations and a second state of the set-reset flip flop is controlled by a timing circuit.

18. The in-memory computation circuit of claim 17, wherein the timing circuit comprises:
a first counter circuit configured to generate a first incrementing count value;
a second counter circuit configured to generate a second incrementing count value;
a first comparison circuit enabled by a first logic state of the sign bit to compare the coefficient value specified by the latched plurality of data bits to the first incrementing count value and generate a signal controlling the second state based on the first comparison; and
a second comparison circuit enabled by a second logic state of the sign bit to compare the coefficient value specified by the latched plurality of data bits to the second incrementing count value and generate the signal controlling the second state based on the second comparison.

19. An in-memory computation circuit, comprising:
a memory array including a plurality of memory cells arranged in a matrix with plural rows and plural columns, wherein groups of memory cells store computational weights for an in-memory compute (IMC) operation that is performed with a first multiply and accumulate (MAC) elaboration and a second MAC elaboration, each row of groups of memory cells including a positive word line coupled to first and second memory cells in each group of memory cells and a negative word line coupled to third and fourth memory cells in each group of memory cells, and each column of groups of memory cells including a positive bit line coupled to the first and third memory cells of each group of memory cells and a negative bit line coupled to second and fourth memory cells of each group of memory cells;
a row controller circuit configured to receive signed coefficient data for the IMC operation and generate during each of the first and second MAC elaborations a pulsed word line signal for application to the positive word line when the signed coefficient data is positive, and generate a pulsed word line signal for application to the negative word line when the signed coefficient data is negative; and
a column processing circuit coupled to the positive and negative bit lines and configured to: a) sense a first analog signal developed on the positive bit line during the first MAC elaboration; and b) sense a second signal developed on the negative bit line during the second MAC elaboration.

20. The in-memory computation circuit of claim 19, wherein the column processing circuit is further configured to process the first and second analog signals to generate a result of the IMC operation.

21. The in-memory computation circuit of claim 20, wherein the processing of the first and second analog signals to generate the result of the IMC operation comprises determining a difference between the first and second analog signals.

22. The in-memory computation circuit of claim 19, wherein the row controller circuit is further configured to identify a plurality of rows of groups of memory cells to be simultaneously selected for receiving pulsed word line signals during the first and second MAC elaborations of the IMC operation.

23. The in-memory computation circuit of claim 19, wherein the signed coefficient data for the IMC operation is in a signed binary format including a sign bit and a plurality of data bits providing a coefficient value, and wherein the row controller circuit is further configured to control a pulse width of the pulsed word line signal dependent on the coefficient value.

24. The in-memory computation circuit of claim 23, wherein the row controller circuit comprises, for each row of groups of memory cells:
a data latch configured to latch the sign bit and plurality of data bits for the signed coefficient data;
a counter circuit configured to generate an incrementing count value; and
a comparison circuit configured to compare the coefficient value specified by the latched plurality of data bits to the incrementing count value and control a trailing edge of the pulse width of the pulsed word line signal based on the comparison.

25. The in-memory computation circuit of claim 23, wherein the row controller circuit comprises, for each row of groups of memory cells:
a data latch configured to latch the sign bit and plurality of data bits for the signed coefficient data;
wherein the sign bit provides a control signal for selecting one of the positive and negative word lines for application of the pulsed word line signal;
a first logic gate having a first input coupled to receive the control signal, a second input configured to receive the pulsed word line signal, and an output coupled to the positive word line; and
a second logic gate having a first input coupled to receive a logical inverse of the control signal, a second input configured to receive the pulsed word line signal, and an output coupled to the negative word line.

26. The in-memory computation circuit of claim 25, further including a set-reset flip flop configured to generate the pulsed word line signal.

27. The in-memory computation circuit of claim 26, wherein a first state of the set-reset flip flop is controlled by a start of each of the first and second MAC elaborations and a second state of the set-reset flip flop is controlled by a timing circuit.

28. The in-memory computation circuit of claim 27, wherein the timing circuit comprises:
a counter circuit configured to generate an incrementing count value; and
a comparison circuit configured to compare the coefficient value specified by the latched plurality of data bits to the incrementing count value and generate a signal controlling the second state based on the comparison.
